(19) United States
(12) Patent Application Publication
(10) Pub. No.: US 2009/0127692 A1
(43) Pub. Date: May 21, 2009

(54) METHOD OF CONNECTING A SEMICONDUCTOR PACKAGE TO A PRINTED WIRING BOARD

(76) Inventors: Kohichiro Kawate, Tokyo (JP); Yoshiaki Sato, Tokyo (JP); Miwa Monma, Tokyo (JP); Yoshihisa Kawate, Tokyo (JP)

Correspondence Address: 3M INNOVATIVE PROPERTIES COMPANY, PO BOX 33427, ST. PAUL, MN, 55133-3427, US

(21) Appl. No.: 11/577,921

(22) PCT Filed: Oct. 14, 2005
(86) PCT No.: PCT/US05/37287

§ 371 Date: Apr. 25, 2007

(30) Foreign Application Priority Data
Nov. 1, 2004 (JP) 2004-318225

(51) Int. Cl. H01L 23/498; H01L 21/98

(52) U.S. Cl. 257/692; 438/108; 257/E23.068; 257/E21.705

(57) ABSTRACT

A method of electrically connecting a bump array package to a wiring board, comprising the steps of:
arranging a thermofluidizing, thermosetting adhesive film on a surface of a bump array package having metal bumps; creating a bump array package having a flat surface comprising said metal bumps and said adhesive film, and
connecting the bump array package to the wiring board by arranging the flat surface comprising said metal bumps and said adhesive film on the wiring board, and heating the adhesive film at a temperature high enough for finishing the setting of said adhesive film and higher than the melting temperature of said solder.

### TECHNICAL FIELD

This invention relates to a method of connecting a semiconductor package to a printed wiring board.

### BACKGROUND

Area bump array packages such as a ball grid array (BGA) or chip scale package (CSP) or bumped wafer having input/output terminals of the semiconductor chip as metal bumps being arranged in a two-dimensional manner are very effective in decreasing the size of the semiconductor device and have nowadays been employed in many semiconductor packages.

When the area bump array package is connected to a printed wiring board, thermal stress acts upon the bump junction portions due to a difference in the thermal expansion coefficient between the printed wiring board and the package. The thermal stress often breaks the electric connection, thus spoiling the reliability of connection. To avoid this problem, a gap formed in the bump junction portion between the semiconductor package and the printed board is filled with an under-filling material. There has heretofore been used an under-filling material of the type of a liquid resin poured by utilizing the capillary phenomenon between the semiconductor package and the substrate after the metal bumps (for example solder balls) have been joined to the wiring board (this method is called “after-pouring”).

The semiconductor packages have been realized in ever small sizes to meet the demand for highly densely fabricating the electronic equipment, and have been furnished with increased numbers of input/output terminals to meet an increase in the functions. As a result, the distance between the bumps must be decreased, and the diameter of the bump has been decreased correspondingly. Therefore, the gap becomes narrow between the semiconductor package and the wiring board, and it is becoming difficult to pour the resin of the liquid type. From the standpoint of a high degree of integration, further, it is becoming necessary to mount other parts near the semiconductor package mounted on the printed wiring board making it further difficult to pour the liquid resin.

Under such circumstances, a pre-pouring under-fill technology has been devised to introduce the sealing resin prior to connecting the bumps. Patent document 1 (U.S. Pat. No. 6,624,216) and patent document 2 (U.S. Pat. No. 5,128,746) propose under-filling adhesives containing a flux component. In this case, however, it is difficult to keep both properties required for flux and properties required for sealing material and it is considered that properties of pre-pouring under-filling adhesive are deteriorated as compared to those obtained by the after-pouring of the liquid resin. Pre-pouring under-filling adhesive usually include a strong acid such as acid anhydride. The residual of acid components causes deterioration of electrical insulation property of the cured material. For example, ion migration may occur as a result of acid residual to deteriorate electrical insulation property.

Patent document 3 (U.S. Pat. No. 6,297,560) and patent document 4 (U.S. Pat. No. 6,228,678) propose methods in which a sealing resin is applied prior to forming solder balls, the resin perforated by removing the input/output terminal portions of the semiconductor chip by etching or laser working, and the paste is introduced into the holes and is melted in the reflowing step so as to be joined as solder balls to the wiring board. This method is suited for machining into chips on a wafer level, but cannot be applied to a package that contain an individual chip.

Patent document 5 (U.S. Pat. No. 6,265,776) discloses a method in which a flux is applied to the solder balls, and an under-filling adhesive is applied thereon so as to be connected to a wiring board. Since the flux having a low surface energy is existing at the ends of the solder balls, the under-filling adhesive is expelled. That is, no under-filling agent exists at the ends of the balls, and only the peripheries thereof are sealed with an adhesive resin. According to this technology, in order that the under-filling adhesive does not adhere to the ends of balls, the under-filling adhesive must be applied as a resin solution dissolved in a solvent and must be dried, which makes the process complex. Further, the ends of the solder balls are elevated and it is probable that a gap may develop between the wiring board and the package when the wiring board comes in contact with the ends of solder balls on the package at the time of connection, making it difficult to fill the under-filling adhesive to a sufficient degree.

Patent document 6 (Japanese Unexamined Patent Publication (Kokai) No. 2003-243447) discloses a method of electrically connecting a semiconductor element to a wiring board by pressing sharply protruded electrodes onto the wiring board via a thermosetting adhesive sheet followed by thermosetting. According to this method, it is necessary that the electrodes are protruded having sharp ends in order to maintain reliable electric contact between the electrodes on the side of the semiconductor element and the land on the side of the wiring board at the time of pressing. In this case, it is also probable that a gap develops between the wiring board and the semiconductor element in bringing the wiring board into contact with the protruded electrodes on the semiconductor element at the time of connection, making it difficult to fill the under-filling adhesive to a sufficient degree.

### BRIEF DESCRIPTION OF THE DRAWINGS

FIG. 1 is a view of steps illustrating a method of the present invention.

FIG. 2 is a bottom view of a bump array package.

FIG. 3 is a view of a circuit used in the Example.

### DISCLOSURE OF THE INVENTION

It is therefore an object of the present invention to provide a method of electrically connecting a semiconductor package to a wiring board maintaining reliability in the connection and requiring easy operation.

Another object of the present invention is to provide a semiconductor package with a thermosetting adhesive film that can be used in the above-mentioned method of electric connection.

According to one aspect of the invention, there is provided a method of electrically connecting a bump array package to a wiring board, comprising the steps of:

arranging a thermofluidizing, thermosetting adhesive film on a surface of a bump array package having metal bumps; creating a bump array package having a flat surface comprising said metal bumps and said adhesive film, and

connecting the bump array package to the wiring board by arranging the flat surface comprising said metal bumps and said adhesive film on the wiring board, and heating the adhesive film at a temperature high enough for finishing the setting of said adhesive film and higher than the melting temperature of said metal bumps.

According to a more specific embodiment of such a method, there is provided a method of electrically connecting a bump array package to a wiring board as described above, the bump array package having a plurality of metal bumps on a planar surface as input/output terminals of a semiconductor chip, comprising the steps of:

arranging a thermofluidizing, thermosetting adhesive film on the surface of said bump array package having metal bumps; creating a bump array package having a flat surface comprising said metal bumps and said adhesive film in which the ends of said metal bumps are partially flattened and are exposed on the surface by pressing said adhesive film with a plate having a flat surface at a temperature high enough for said adhesive film to be fluidized but not high enough for finishing the setting of said adhesive film and is lower than the melting temperature of said metal bumps, and

connecting the bump array package to the wiring board by arranging the flat surface comprising said metal bumps and said adhesive film on the wiring board, and heating the adhesive film at a temperature high enough for finishing the setting of said adhesive film and higher than the melting temperature of said metal bumps.

According to another aspect of the invention, there is provided a bump array package with an adhesive film, in which the ends of metal bumps are partially flattened and are exposed on the surface, thereby having a flat surface comprising said metal bumps and said adhesive film.

According to a more specific embodiment, there is provided a bump array package with an adhesive film as described above, in which the ends of metal bumps are partially flattened and are exposed on the surface, thereby having a flat surface comprising said metal bumps and said adhesive film, obtained by preparing a bump array package having a plurality of metal bumps on a planar surface as input/output terminals of a semiconductor chip, arranging a thermofluidizing, thermosetting adhesive film on the surface of said bump array package having metal bumps, and pressing said adhesive film with a plate having a flat surface at a temperature high enough for said adhesive film to be fluidized but not high enough for finishing the setting of said adhesive film and lower than the melting temperature of said metal bumps. Wherein metal bumps include solder bumps, gold bumps, copper bumps.

According to more another aspect of this invention, there is provided a gold bumped semiconductor chip.

Unlike the method that uses a liquid resin utilizing the capillary phenomenon, the method of the present invention makes it possible to electrically connect a highly densely integrated bump array package to a wiring board effectively, and efficiently.

The method of the invention is a dry process without using solvent. Therefore, no step is required for removing the solvent and there is no problem of contamination of the package by the solvent.

Further, since no flux is contained in the adhesive film, the step of connection can be conducted after the conventional flux is applied onto the wiring board.

The method of this invention does not require fine working such as laser working, and can be easily applied even to a package comprising an individual chip.

In the method of the invention, further, an adhesive film is arranged on the metal bump surfaces of the bump array package, and is heated and pressed so as to be fluidized to obtain a flat surface in a state where the metal bumps are exposed. Since the resulting surface is flat, the contact to the wiring board is accomplished without gap. In the next step of connection, therefore, the setting is effected and the solder is melted in a state where the resin of the adhesive film is sufficiently filled.

A preferred embodiment of the invention will now be described, which, however, is in no way to limit the present invention.

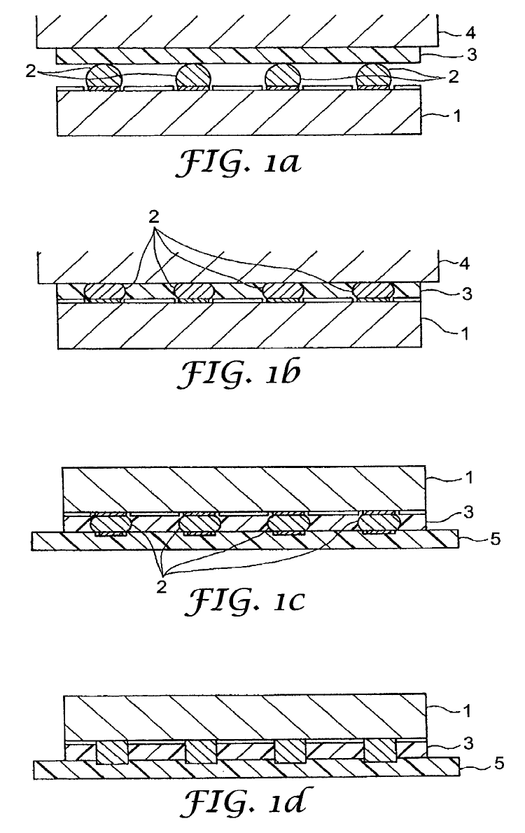

First, the invention will be described in conjunction with the drawings. FIG. 1 is a view of steps illustrating a method of electrically connecting a bump array package to a wiring board. The “bump array package” is a semiconductor package having a plurality of metal bumps on a planar surface as input/output terminals of the semiconductor chip. Concretely speaking, there can be exemplified area bump array packages such as a ball grid array (BGA), a chip scale package (CSP) and a wafer level CSP, bumped wafer. These bumps may be formed by reflow process or plating process or wire-bonding process. The bump array package 1 has, on the surface thereof, metal bumps 2, usually, having spherically curved surfaces. A thermofluidizing, thermosetting adhesive film 3 is arranged on the side of the metal bumps 2 of the package 1 (FIG. 1(a)) and is, thereafter, heated and pressed by a heating plate 4 having a flat surface so that it fluidized and flows around the metal bumps, permitting the ends of the metal bumps 2 to be exposed in a flattened state. There is thus obtained the package 1 with the adhesive film 3 and having a flat surface comprising the adhesive film 3 and the exposed surfaces of the metal bumps 2 (FIG. 1(b)). The above process can be effected by the following steps. Usually, the adhesive film is disposed on the metal bumps of the bump array package, the adhesive film is covered by a release film such as a polytetrafluoroethylene (PTFE) film or a silicone-treated polyester film, and elevated temperature and pressure are applied onto the film. Such heating and pressurizing step can be effected by using a thermal bonder such as a pulse heat bonder. A bonder with bonder head having a size of greater than the size of chip should be used. A stress should be applied in a vertical direction to the chip.

The temperature heated by the heating plate 4 is high enough for fluidizing the adhesive film 3 but not high enough for finishing the setting of the adhesive film 3, and lower than the melting temperature of the metal bumps.

The pressing pressure is large enough for the ends of the metal bumps 2 to be flattened and exposed on the surface. The above temperature and pressure are determined by the resin composition of the adhesive film that is selected and the melting point of the metal bumps, and are not limited. In the method of this invention, in general, it is desired to use an adhesive film containing a resin component having a fluidizing temperature of 60 to 170° C. and a setting temperature of 170 to 260° C., and to use a solder having a melting point of 180 to 300° C. Preferably in this case, the heating temperature is about 100 to about 180° C., the heating time is 1 to 10 seconds, and the pressing pressure is 5 to 100 N/cm².

The “fluidizing temperature” is a temperature at which the viscosity of the polymer resin becomes smaller than 10,000 Pa·s, and can be measured by using a flat plate-type viscometer (plastometer) or a viscosity measuring machine, and the “setting temperature” is a temperature at which the thermosetting reaction of the thermosetting polymer proceeds by more than 50% in 60 minutes, and can be measured by using a viscosity measuring machine or a differential scanning calorimeter (DSC). Here, the words “temperature not enough for finishing the setting”, usually, means a temperature lower than the setting temperature. Even when the temperature is higher than the setting temperature, the setting takes place only partly if the heating is for only a short period of time. Therefore, the above defined temperature encompasses the heating for a short period of time at a temperature higher than the setting temperature.

Next, the flat surface comprising the metal bumps 2 and the adhesive film 3 of the package 1 with the adhesive film 3 is arranged on a wiring board (FIG. 1(c)), and is heated at a temperature high enough for finishing the setting of the adhesive film 3 and higher than the melting temperature of the metal bumps in order to connect the bump array package to the wiring board (FIG. 1(d)). The wiring board is, usually, a printed wiring board and, usually, has copper wiring formed on a resin substrate such as of a glass epoxy substrate. It is further allowable to use a resin plate of a bismaleimide triazine resin (BT resin) a polyimide an aramide based resin substrate as the substrate. The temperature for connecting the bump array package to the wiring board is determined depending upon the resin composition of the adhesive film that is selected and the melting point of the metal bumps, and is not limited. When the above adhesive film and the solder are used in the method of the present invention, the heating temperature is about 180 to 280° C. and the heating time is 30 to 300 seconds to favorably accomplish the connection. In this step, the resin component in the adhesive film expands and the solder melts, whereby the molten solder is extruded by the thermal expansion of the adhesive and is connected to the wiring on the wiring board. Prior to arranging the package 1 with the adhesive film 3 on the wiring board 5, it is desired to apply the flux to a portion to where the wiring board 5 is to be connected in order to promote the connection by soldering. The flux is the one that has heretofore been widely used in this field of art. After the package 1 with the adhesive film 3 is arranged on the wiring board 5, the wiring board 5 is passed through a reflow oven heated at the above-mentioned temperature to effect the step of connection.

When the above adhesive film and the gold bumps are used in a method of the present invention, the bumped chip is preferably heat pressed on the printed circuit board to attain metallurgical bonding or physical contact between the bumps and circuits on the PCB. To apply ultrasonic vibration at the contact points is useful to strengthen the interconnection.

The method of the invention uses an adhesive film (hereinafter also referred to as “thermosetting adhesive film” or “adhesive film”) containing a thermofluidizing, thermosetting resin (hereinafter also referred to as “thermosetting resin”) that is fluidized when heated to a certain temperature and is set when further heated. The above thermosetting resin contains both a thermoplastic component and a thermosetting component. The thermoplastic component and thermosetting component can be present in the same polymer compound or can be a mixture of a thermoplastic resin and a thermosetting resin. As a example of the case, where the thermoplastic component and thermosetting component are present in the same polymer compound, an epoxy resin modified with a thermoplastic component, such as a polycaprolactone-modified epoxy resin, rubber-modified epoxy resin can be exemplified. Another example includes a copolymer resin having a thermosetting group such as an epoxy group on the basic structure of a thermoplastic resin. As the above copolymer resin, there can be exemplified a copolymer of, for example, an ethylene and a glycidyl (meth)acrylate. The resin containing both a thermoplastic component and a thermosetting component can be used alone, or used with another thermoplastic component and/or a thermosetting component. For example, in the case of a caprolactone-modified epoxy resin, if a molecular weight of caprolactone is high, it does not need to be used with another thermoplastic resin and thus used alone, because a sufficient fluidity can be obtained. On the other hand, if a molecular weight of caprolactone is low, it may be advantageous to use the resin with another thermoplastic resin. The composition of resin should be appropriately determined by a person with ordinary skill in the art.

An adhesive composition that can be particularly favorably used for the adhesive film is a thermosetting adhesive composition containing a caprolactone-modified epoxy resin.

The above thermosetting adhesive composition usually has a crystal phase. In particular, the crystal phase contains a caprolactone-modified epoxy resin (hereinafter also referred to as “modified epoxy resin”) as a chief component. The modified epoxy resin imparts a suitable degree of flexibility to the thermosetting adhesive composition to improve viscoelastic properties of the thermosetting adhesive. As a result, the thermosetting adhesive agent exhibits a cohesive force even before being set, and exhibits sticking force by heating. Further, like the ordinary epoxy resin, the modified epoxy resin forms a body that is set having a three-dimensional network structure upon the heating to impart cohesive force to the thermosetting adhesive.

From the standpoint of improving the initial adhering force, the modified epoxy resin, usually, has epoxy equivalents of about 100 to about 9,000, preferably, about 200 to about 5,000 and, more preferably, about 500 to about 3,000. The modified epoxy resins having the above epoxy equivalents have been placed in the market by Daicel Chemical Co. Ltd., in the trade designation of PLUXCEL G Series.

The thermosetting adhesive composition preferably contains a malamine/isocyanuric acid adduct (hereinafter also referred to as “melamine/isocyanuric acid complex”) in combination with the above modified epoxy resin. A utilizable melamine/isocyanuric acid complex has been placed in the market by, for example, Nissan Kagaku Kogyo Co., in the trade name of MC-600, and is effective in toughening the thermosetting adhesive composition, in decreasing the tack of the thermosetting adhesive composition before being thermally set and in suppressing the hygroscopic property and fluidity of the thermosetting adhesive composition. Additionally, this component is effective to adjust the viscosity of the adhesive, particularly effective to increase the viscosity of the adhesive in the soldering process. If the viscosity of adhesive is too small, the adhesive may spread out of the chip area. On the other hand, if the viscosity of adhesive is too high, it may disturb the soldering process. Therefore, the viscosity of adhesive should be strictly controlled and the above component functions as a viscosity controlling agent. In order to prevent brittleness after thermally set without impairing the above-mentioned effects, the thermosetting adhesive composition can contain the melamine/isocyanuric acid complex usually in an amount of 1 to 200 parts by weight, preferably, 2 to 100 parts by weight and, more preferably, 3 to 50 parts by weight per 100 parts by weight of the modified epoxy resin.

The thermosetting adhesive composition may, further, contain a second epoxy resin (hereinafter also simply referred to as “epoxy resin”) in combination with the phenoxy resin or independently therefrom. There is no particular limitation on the second epoxy resin as long as it does not depart from the scope of the invention, and there can be used bisphenol A epoxy resin, bisphenol F epoxy resin, bisphenol A diglycidyl ether epoxy resin, phenol novolak epoxy resin, cresol novolak epoxy resin, fluorene epoxy resin, glycidylamine resin, aliphatic epoxy resin, brominated epoxy resin and fluorinated epoxy resin. Like the modified epoxy resin, the above epoxy resins are compatible with the phenoxy resin, and are rarely bled from the thermosetting adhesive composition. In particular, the heat resistance is advantageously improved when the thermosetting adhesive composition contains the second epoxy resin in an amount of, preferably 50 to 200 parts by weight and, more preferably, 60 to 140 parts by weight per 100 parts by weight of the modified epoxy resin.

In the embodiment of this invention, in particular, the bisphenol A diglycidyl ether epoxy resin (hereinafter also referred to as “diglycidyl ether epoxy resin”) can be used as a preferred second epoxy resin. The diglycidyl ether epoxy resin is a liquid and works to improve high-temperature properties of the thermosetting adhesive composition. For example, use of the diglycidyl ether epoxy resin makes it possible to improve resistance against chemicals relying upon the setting at a high temperature and to improve the glass transition temperature. Further, a setting (curing) agent can be broadly selected and the setting conditions become relatively mild. The above diglycidyl ether epoxy resin has been placed in the market by, for example, Dow Chemical (Japan) Co., in the trade designation of D.E.R. 332. Another preferred second epoxy resin is commercially available as YD128 from Tohto Chemical, Ltd.

As required, the setting agent is added to the thermosetting adhesive composition, so that the modified epoxy resin and the second epoxy resin take part in the setting reaction. There is no particular limitation on the amount and kind of the setting agent so far as it exhibits the desired effect. From the standpoint of improving the heat resistance, however, the setting agent is contained, usually, in an amount of 1 to 50 parts by weight, preferably, 2 to 40 parts by weight and, more preferably, 5 to 30 parts by weight per 100 parts by weight of the modified epoxy resin and the required second epoxy resin. Though not limited to those listed below, examples of the setting agent that can be used include amine setting agent, acid anhydride, dicyandiamide, cationic polymerization catalyst, imidazole compound, hydrazine compound, phenol and the like. In particular, the dicyandiamide is a promising setting agent having thermal stability at room temperature. It is further desired to use an alicyclic polyamine or polyamide, amideamine or a modified product thereof for a glycidyl ether type epoxy resin.

By adding 35 to 100% of organic particles based on the total mass of the adhesive film, the adhesive film comprising the above thermosetting adhesive composition exhibits effects as described below. The resin exhibits plastic fluidity upon the addition of organic particles. When the metal bumps are pushed with a relatively high pressure, the resin having the above property fluidizes enabling the metal bumps to penetrate through so as to be exposed to the surface. The organic particles, on the other hand, suppress excess of fluidity of the thermosetting adhesive composition, and prevent the thermosetting adhesive composition from flowing out in the step of exposing the metal bumps by using a heating plate. In the step of connection to the wiring board, further, water adhered to the wiring board may vaporize during the heating to produce the water vapor pressure. In this case, too, the resin fluidizes so as not to entrap the bubbles.

Further, the organic particles that are added are those of acrylic resin, styrene/butadiene resin, styrene/butadiene/acrylic resin, melamine resin, melamine/isocyanurate adduct, polyimide, silicone resin, polyetherimide, polyethersulfone, polyester, polycarbonate, polyether ether ketone, polybenzoimidazole, polyarylate, liquid crystal polymer, olefinic resin, or ethylene/acrylic copolymer, and their sizes are not larger than 10 μm and, preferably, not larger than 5 μm.

The adhesive film may contain inorganic fillers such as silica, aluminum oxide and glass beads. The inorganic filler suppresses the coefficient of thermal expansion of the adhesive film after setting, making it possible to avoid thermal stress in the tangential portions.

It is desired that the adhesive film has a thickness smaller than the height of the metal bumps. This is because if the adhesive film and the bump array package are heat-press-adhered together, the metal bumps penetrate through the adhesive film, and the package with the adhesive film is obtained in a state where the ends of the solder balls are exposed in a flattened manner. Though this is not to impose any limitation, it is desired that the metal bumps, usually, have a height of 50 to 1000 μm and the adhesive film has a thickness of 25 to 500 μm to correspond thereto. The ratio of the thickness of the adhesive film to the height of the metal bumps is, preferably, 0.3 to 0.8.

As described above, the metal bumps are, usually, of a spherical shape having a height of 50 to 1000 μm or conical shape having a height of 50 to 1000 μm. It is desired that the bumps are crushed to 50 to 90% of the initial height so as to partially flatten the ends of the bumps, i.e., the bumps are deformed by 10 to 50% in the direction parallel to height of the bumps. Within these ranges, the molten solder is extruded by the expansion of the adhesive film during the step of connection, and the connection is favorably accomplished.

### EXAMPLE

The method of the invention will now be described by way of an Example.

### Bump Array Package and Wiring Board.

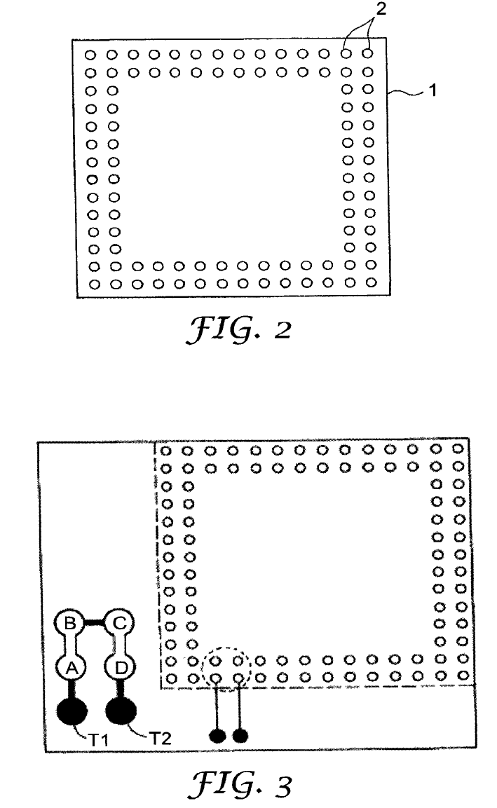

A ball grid array (BGA) purchased from Top Line Co. was used as a bump array package. FIG. 2 is its bottom view. The BGA was a semiconductor package including a polyimide (PI) interposer, measuring 8×8 mm in size, having the solder balls arranged maintaining a pitch of 0.5 mm with a ball height of 0.31 mm (tin/lead solder), which are arranged in a number of 14×14 along the outer circumference and in a number of 12×12 along the inner circumference.

A glass epoxy substrate (thickness: 0.5 mm) having thereon a conducting pattern having a pitch corresponding to the pitch of the solder balls on the bump array package was used as a wiring board.

### Adhesive Film.

An adhesive resin solution of a composition shown in Table 1 below was prepared, applied onto a silicone-treated polyethylene terephthalate (PET) film by knife coating, and was dried in an oven heated at 100° C. for 20 minutes to obtain a film having a thickness of 25 μm. The same operation was repeated another five times. Six pieces of the obtained films were heat-laminated at 120° C. to form an adhesive film having a thickness of 150 μm.

TABLE 1
Resin composition

| Component | Parts by weight |
|---|---|
| YP50S | 30 |
| YD128 | 34 |
| G402 | 30 |
| BAFL | 16.4 |
| MC600 | 20 |
| EXL2314 | 80 |
| THF | 600 |

Phenoxy resin: YP50S, Tohto Chemical, number average molecular weight 11,800
Epoxy resin: YD128, Tohto Chemical, epoxy equivalent=184-194
Polycaprolactone modified epoxy resin: G402, Daicel Chemical Co. Ltd. epoxy equivalent 1350
Bisanilinefluorene: BAFL, Nippon Steel Chemical Co. Ltd.
Acrylic particle: EXL2314, KUREHA PARALOID EXL, Kureha Chemical, Co., Ltd.
Melamine isocyanuric Acid Complex: MC-600 Nissan Chemical Industries, Ltd.
THF: tetrahydrofuran

With the surface of the bump array package having solder balls facing upward, the above adhesive film was arranged on the solder balls and was heat-press-adhered thereto by being pressed by a thermal head of a pulse heat bonder (TCW-215/NA-66 (trade name), manufactured by Nihon Abionics Co.) with a load of 50 N via a silicone-treated PET film of a thickness of 50 μm. The temperature of the thermal head was elevated from room temperature up to 130° C. in two seconds, and this temperature was maintained for one second. Thereafter, the temperature was elevated up to 160° C. in one second, and this temperature was maintained for three seconds. As a result, the bump array package with the adhesive film was obtained having a cross section as illustrated in FIG. 1(b) in which the solder balls were completely penetrating through the adhesive film and possessed flattened ends.

A flux (Deltalux 523H (trade name), manufactured by Senju Kinzoku Kogyo Co.) was applied onto a connection portion of the wiring board having an electrically conducting pattern corresponding to the ball pitch, and the bump array package with the adhesive film was overlapped thereon in a manner that the adhesive film was in agreement with the connection portion of the electrically conducting pattern of the wiring board. The assembly was passed through a solder reflow oven (150° C. in a preheating zone, a maximum temperature of 240° C.) in a total of 180 seconds to effect the soldering.

The electric connection was effected at four places A to D as shown in FIG. 3 to connect the circuits of T1 and T2. In the above example, therefore, there were formed 24 circuits connecting T1 and T2. After the solder reflowing, the resistance was measured between the terminals T1 and T2 on the wiring board, and it was confirmed that 24 circuits had all been connected. The sample was subjected to a heat cycle between −40° C. and 80° C. (30 minutes at each temperature) 1000 times to find an increase in the resistance of not larger than 5%.

1-10. (canceled)

11. A method of electrically connecting a bump array package to a wiring board, comprising the steps of:
arranging a thermofluidizing, thermosetting adhesive film on a surface of a bump array package having metal bumps; creating a bump array package having a flat surface comprising said metal bumps and said adhesive film, and
connecting the bump array package to the wiring board by arranging the flat surface comprising said metal bumps and said adhesive film on the wiring board, and heating the adhesive film at a temperature high enough for finishing the setting of said adhesive film and higher than the melting temperature of said solder.

12. A method of electrically connecting a bump array package to a wiring board according to claim 11, the bump array package having a plurality of metal bumps on a planar surface as input/output terminals of a semiconductor chip, comprising the steps of:
arranging a thermofluidizing, thermosetting adhesive film on the surface of said bump array package having metal bumps; creating a bump array package having a flat surface comprising said metal bumps and said adhesive film in which the ends of said metal bumps are partially flattened and are exposed on the surface by pressing said adhesive film with a plate having a flat surface at a temperature high enough for said adhesive film to be fluidized but not high enough for finishing the setting of said adhesive film and is lower than the melting temperature of said metal bumps, and
connecting the bump array package to the wiring board by arranging the flat surface comprising said metal bumps and said adhesive film on the wiring board, and heating the adhesive film at a temperature high enough for finishing the setting of said adhesive film and higher than the melting temperature of said metal bumps.

13. A method according to claim 11, wherein said thermofluidizing, thermosetting adhesive film contains both a thermoplastic component and a thermosetting component.

14. A method according to claim 11, wherein said thermofluidizing, thermosetting adhesive film comprises a thermosetting adhesive composition containing a caprolactone-modified epoxy resin.

15. A method according to claim 12, wherein said thermofluidizing, thermosetting adhesive film comprises a thermosetting adhesive composition containing a caprolactone-modified epoxy resin.

16. A method according to claim 11, wherein said thermofluidizing, thermosetting adhesive film contains 35 to 100% of organic particles on the basis of the total mass of said adhesive film.

17. A method according to claim 11, further comprising applying a flux onto a portion to where said wiring board is to be connected prior to arranging the flat surface which comprises said metal bumps and said adhesive film on the wiring board.

18. A method according to claim 12, further comprising applying a flux onto a portion to where said wiring board is to be connected prior to arranging the flat surface which comprises said metal bumps and said adhesive film on the wiring board.

19. A method according to claim 11, wherein the step of connecting the bump array package to the wiring board is conducted in a solder reflow oven.

20. A bump array package with an adhesive film, in which the ends of metal bumps are partially flattened and are exposed on the surface, thereby having a flat surface comprising said metal bumps and said adhesive film.

21. A bump array package with an adhesive film according to claim 20, in which the metal bumps are crushed to 50 to 90% of the initial height of the metal bumps, thereby the ends of metal bumps being partial flattened.

22. A bump array package with an adhesive film according to claim 20, in which the ends of metal bumps are partially flattened and are exposed on the surface, thereby having a flat surface comprising said metal bumps and said adhesive film, obtained by preparing a bump array package having a plurality of metal bumps on a planar surface as input/output terminals of a semiconductor chip, arranging a thermofluidizing, thermosetting adhesive film on the surface of said bump array package having metal bumps, and pressing said adhesive film with a plate having a flat surface at a temperature high enough for said adhesive film to be fluidized but not high enough for finishing the setting of said adhesive film and lower than the melting temperature of said metal bumps.

23. A bump array package with an adhesive film according to claim 21, in which the ends of metal bumps are partially flattened and are exposed on the surface, thereby having a flat surface comprising said metal bumps and said adhesive film, obtained by preparing a bump array package having a plurality of metal bumps on a planar surface as input/output terminals of a semiconductor chip, arranging a thermofluidizing, thermosetting adhesive film on the surface of said bump array package having metal bumps, and pressing said adhesive film with a plate having a flat surface at a temperature high enough for said adhesive film to be fluidized but not high enough for finishing the setting of said adhesive film and lower than the melting temperature of said metal bumps.
